(19) United States
(12) Patent Application Publication
(10) Pub. No.: US 2005/0127165 A1
(43) Pub. Date: Jun. 16, 2005

(54) Systems and methods for credit card charge validation over a network

(76) Inventor: James Christian Currey, El Paso, TX (US)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 10/990,852

(22) Filed: Nov. 17, 2004

Related U.S. Application Data
(60) Provisional application No. 60/520,832, filed on Nov. 17, 2003.

(51) Int. Cl. G06K 5/00; G06F 17/60; H01L 23/02

(52) U.S. Cl. 235/380; 705/17; 705/39

(57) ABSTRACT

Methods and systems consistent with the present invention provide a data processing system that includes a remote data processor operably connected to one or more point of sale systems and to one or more credit card issuer systems on a network. The methods and systems receive a plurality of credit card receipts by the remote data processor from the point of sale system, scan each of the credit card receipts, electronically associate a respective plurality of information items with each scanned credit card receipt, store each of the scanned credit card receipts with the respective plurality of information items, receive a notice of a disputed charge, determine whether a corresponding scanned credit card receipt is stored based on at least one of the plurality of information items associated with each scanned credit card receipt, and transmit the one scanned credit card receipt to a corresponding point of sale system.

### CROSS-REFERENCE TO RELATED APPLICATION

This application claims benefit under 35 U.S.C. §119(e) to provisional patent application Ser. No. 60/520,832 filed on Nov. 17, 2003 entitled “Systems and Methods for Credit Card Charge Validation Over a Network”.

### FIELD OF THE INVENTION

The present invention relates to online systems and methods and, more particularly, to systems and methods that facilitate credit card charge validation over a computer network, such as the Internet.

### BACKGROUND OF THE INVENTION

When a consumer disputes a credit card purchase at a store or point of sale system, an issuer of the credit card typically requires the store to produce proof of the consumer's signature for the transaction. If the store is unable to produce such proof, the charge is often reversed by the credit card issuer and the store absorbs the loss.

Most conventional methods implemented by stores for obtaining proof of the consumer's signature are slow and vary between stores, resulting in the stores losing a substantial amount of money due to the inability of the stores to produce proof of signature or to produce it in a timely manner. In addition, conventional methods for retrieving a credit card receipt with a signature of a person (such as disclosed in Houvener et al, U.S. Pat. No. 6,397,194) often require special equipment for scanning the transaction document at each point of sale location and for storing digital photographs of authorized users of the credit cards to be used for validation of a credit card purchase at the time of the purchase. This special equipment can be expensive to purchase and maintain across an enterprise of stores.

Therefore, a need has long existed for systems and methods that overcome the problems noted above and others previously experienced by stores for validating a credit card purchase.

### SUMMARY OF THE INVENTION

Methods and systems consistent with the present invention provide a validation tool that allows a point of sale system, such as a store or a retailer, to locate a credit card receipt associated with a disputed charge from a group of scanned and stored credit card receipts so that the located credit card receipt can be transmitted to a corresponding credit card issuer for further validation processing.

In accordance with methods and systems consistent with the present invention, a method is provided in a data processing system. The data processing system has a remote data processor and a point of sale system that are each operably connected to a network. The method comprises receiving a plurality of credit card receipts by the remote data processor from the point of sale system, scanning each of the plurality of credit card receipts, and electronically associating a plurality of information items with each scanned credit card receipt. The plurality of information items include at least one of a receipt date, a first identifier for the point of sale system, and a second identifier for an account corresponding to the scanned credit card receipt. The method further comprises storing each of the plurality of scanned credit card receipts with the respective plurality of information items in a storage device operably connected to the remote data processor, receiving a notice of a disputed charge, in response to receiving the notice of the disputed charge, determining whether one of the scanned credit card receipt stored on the storage device corresponds to the disputed charge based on said at least one of the plurality of information items associated with the each scanned credit card receipt, and when it is determined that one of the scanned credit card receipts is stored on the storage device, transmitting the one scanned credit card receipt to either a corresponding point of sale system or a corresponding credit card issuer.

Other systems, methods, features, and advantages of the present invention will be or will become apparent to one with skill in the art upon examination of the following figures and detailed description. It is intended that all such additional systems, methods, features, and advantages be included within this description, be within the scope of the invention, and be protected by the accompanying claims.

### BRIEF DESCRIPTION OF THE DRAWINGS

The accompanying drawings, which are incorporated in and constitute a part of this specification, illustrate an implementation of the present invention and, together with the description, serve to explain the advantages and principles of the invention. In the drawings:

FIG. 1 depicts a block diagram of a data processing system having a remote data processor suitable for practicing methods and implementing systems consistent with the present invention.

FIGS. 2A-2B depict a flow diagram illustrating an exemplary process performed by a validation tool of the data processing system in FIG. 1 to allow a point of sales system to locate an electronic copy of a credit card receipt corresponding to a disputed charge.

FIG. 3 depicts a credit card receipt scanned and stored in association with information items by the validation tool;

FIG. 4 depicts an exemplary user interface transferred by the validation tool to an operator for identification of a credit card account on the scanned credit card receipt; and

FIG. 5 depicts an exemplary user interface generated by the validation tool interface of FIG. 1 to allow a user to submit a request for locating a scanned credit card receipt associated with a disputed charge.

### DETAILED DESCRIPTION OF THE INVENTION

Reference will now be made in detail to an implementation in accordance with methods, systems, and products consistent with the present invention as illustrated in the accompanying drawings. The same reference numbers may be used throughout the drawings and the following description to refer to the same or like parts.

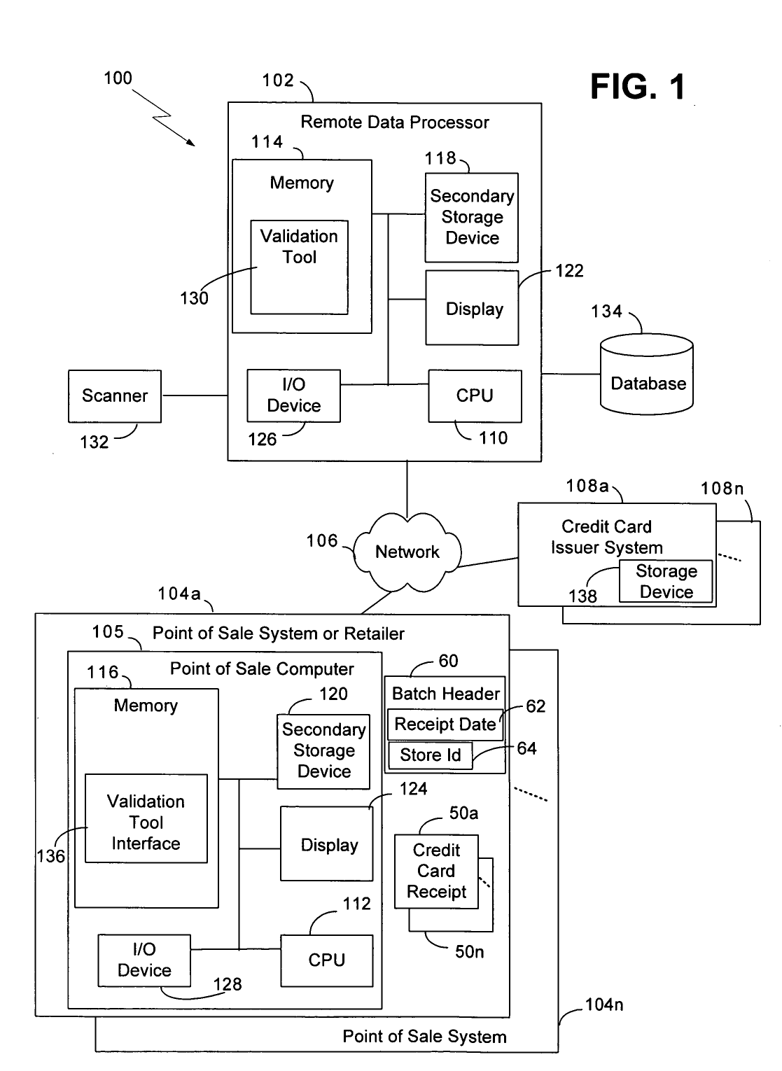

FIG. 1 depicts a block diagram of a data processing system 100 suitable for practicing methods and implementing systems consistent with the present invention. The data processing system 100 includes a remote data processor 102 and one or more point of sale systems 104a-104n. The one or more point of sale systems 104a-104n may correspond to a store, restaurant, or any business location where a person may use a credit card to complete a purchase at the point of sale system and a manual credit card receipt 50a-50n is generated in response to the credit card purchase. In another implementation, the point of sale system 104a may correspond to a retailer that manages or owns stores (e.g., 104b-104n) in which a person may use a credit card to complete a purchase and a manual credit card receipt 50a-50n is produced in response to the credit card purchase.

As shown in FIG. 1, each point of sale system 104a-104n has a point of sale computer 105. The remote data processor 102 and each point of sale system 104a-104n are operably connected via a network 106. The remote data processor 102 and the one or more point of sale systems 104a-104n are preferably in communication with a plurality of credit card issuers 108a-108n via the network 106. The network 106 may be any known private or public communication network, such as a local area network (“LAN”), WAN, Peer-to-Peer, or the Internet, using standard communications protocols. The network 106 may include hardwired as well as wireless branches. As discussed below, a person may dispute a charge on a credit card receipt (e.g., 50a-50n) with a corresponding credit card issuer (e.g., 108a-108n). Either the remote data processor 102, the point of sale system (e.g., 104b-104n) where the transaction associated with the disputed charge took place, or the retailer (e.g., 104a) that owns or manages the point of sale system (e.g., 104b-104n) where the transaction associated with the disputed charge took place may receive the disputed charge from the credit card issuer and then process the disputed charge as discussed below to validate the disputed charge.

The remote data processor 102 and the point of sale computer 105 each include a central processing unit or CPU (110 and 112, respectively), a memory (114 and 116, respectively), a secondary storage device (118 and 120, respectively), a display (122 and 124, respectively), and an I/O device (126 and 128, respectively). The I/O devices 126 and 128 are operably configured to connect the respective computer 102 and 105 to the network 108 and to a scanner 132.

Memory 114 in remote data processor 102 includes a validation tool 130 used in accordance with systems and methods consistent with the present invention to allow the one or more point of sale systems (including a retailer 104a in one implementation) to locate an electronic copy of one of the credit card receipts 50a-50n to validate a disputed charge associated with the one credit card receipt. As discussed in further detail below, the validation tool 130 may operably control the scanner 132 to scan the credit card receipts 50a-50n from each point of sale system 104a-104n, associate respective information items with each scanned credit card receipt 50a-50n, and store the scanned credit card receipts 50a-50n with the associated information items in secondary storage device 118 or in an external database 134 operably connected to the remote data processor.

Memory 116 in the point of sale computer 105 includes a validation tool interface 136 used in accordance with systems and methods consistent with the present invention to allow the retailer or one or more point of sale systems to request that an electronic copy of the credit card receipt associated with the disputed charge (e.g., one of 50a-50n) be located to validate the disputed charge for the corresponding credit card issuer 108a-108n. In one implementation, the validation tool interface 136 may be a known e-mail tool or instant messaging tool that is capable of sending a request across the network 106. In another implementation, the validation tool interface includes a web browser, such Microsoft™ Internet Explorer or Netscape Navigator, that is capable of accessing a web page associated with the validation tool 130 for submitting a request across the network 108.

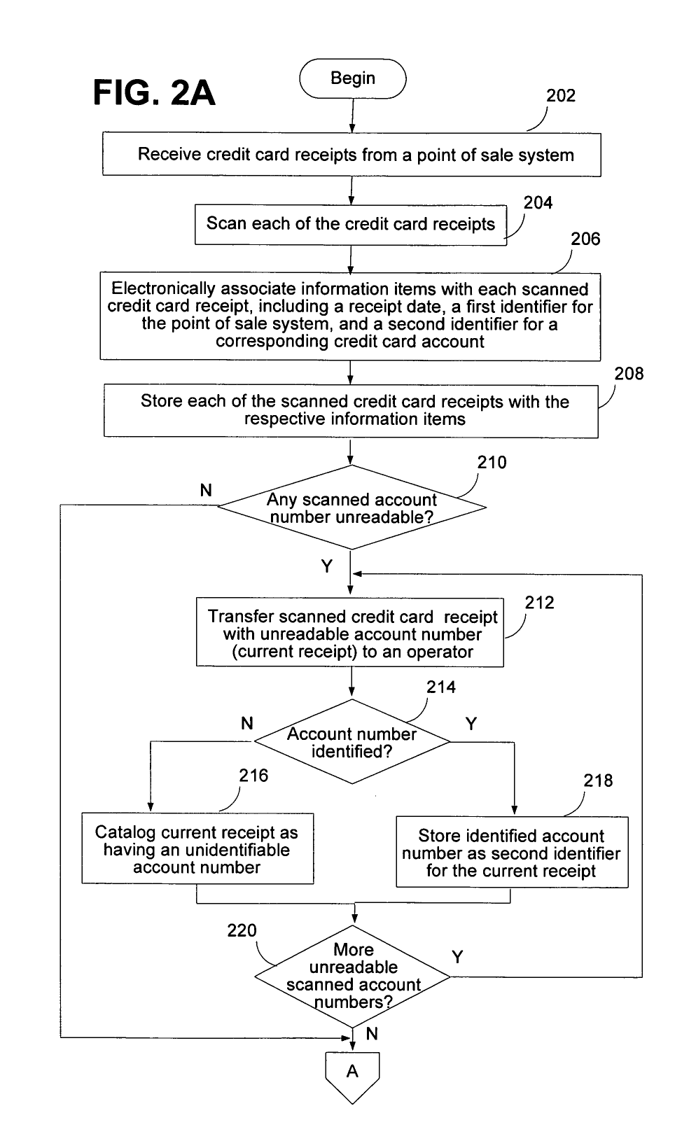

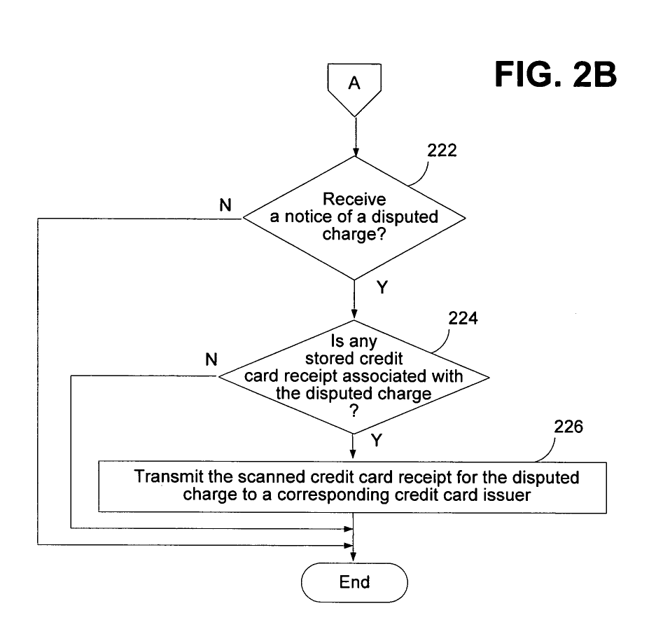

FIGS. 2A-2B depict a flow diagram of a process performed by the validation tool 130 of the remote data processor 102 to allow a point of sale system to locate an electronic copy of a credit card receipt corresponding to a disputed charge. Initially, the validation tool 130 of the remote data processor 102 receives credit card receipts (e.g., credit card receipt 50) from the one or more of the point of sale systems 104a-104n. (Step 202). In one implementation, each point of sale system 104a-104n periodically provides paper copies of credit card receipts 50 corresponding to recent purchases at the respective point of sale system 104 via mail, facsimile or other known transfer means. In another embodiment in which the point of sale system (e.g., 104a) is a retailer that manages or owns other point of sale systems (e.g., 104b-104n), the retailer 104a periodically provides paper copies of credit card receipts 50a-50n corresponding to purchases on a pre-determined date at one or more of the point of sale systems 104b-104n via mail, facsimile or other known transfer means. In this implementation, the retailer 104a or point of sale system 104b-104n may provide the credit card receipts 50a-50n in a batch, such as in a bag or bound bundle, with a batch header 60. Alternatively, the remote data processor 102 or an operator associated with the remote data processor 102 may apply the batch header 60 to the batch of credit card receipts 50a-50n when the batch is received from the retailer 104a or the point of sale system 104a-104n. The batch header 60 has a store identifier 62 to indicate the store or point of sale system 104b-104n where the credit card receipts 50a-50n in the batch originated. The batch header 60 may also include a receipt date 64 that indicates the date that the credit card receipts were generated at the respective store or point of sale system 104b-104n. The batch header 60 may be bar coded and removeably affixed to the batch of credit card receipts 50a-50n.

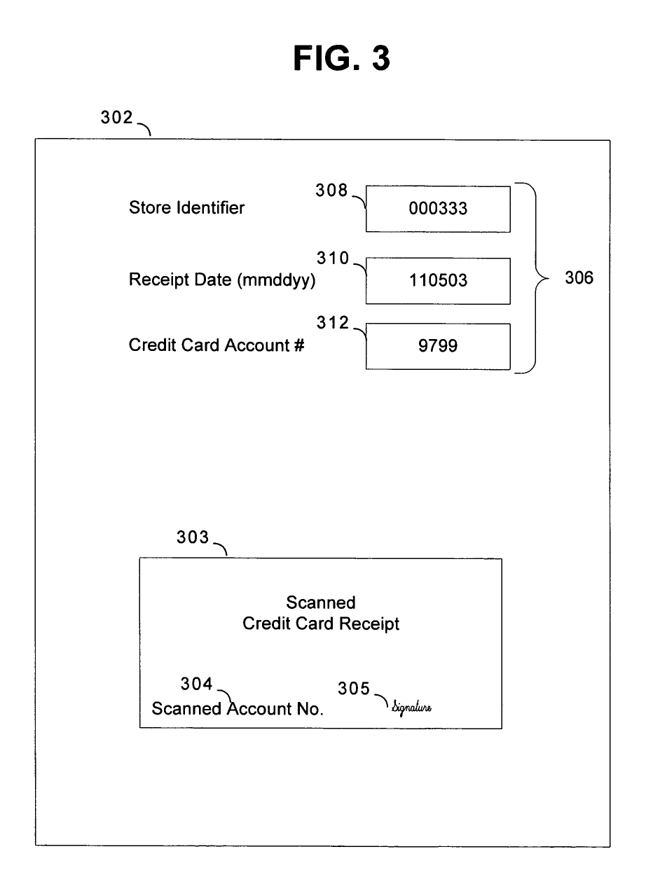

The validation tool 130 scans each of the credit card receipts 50a-50n. (Step 204). In one implementation in which the credit card receipts 50a-50n are received in a batch with a batch header 60, the validation tool 130 first scans the batch header 60 to identify the store id 62 and the date 64 associated with each of the credit card receipts in the batch. The validation tool 130 then electronically associates a plurality of information items with each scanned credit card receipt 50a-50n. (Step. 206). The information items associated with each scanned credit card receipt 50a-50n allows either the remote data processor 102, the retailer 104a, or a respective point of sale system 104b-104n to locate and retrieve one of the credit card receipts 50a-50n to support validation of a disputed charge. FIG. 3 depicts an exemplary user interface 302 produced by the validation tool 130 to illustrate a credit card receipt 303 having an account number 304 and a signature 305 that is scanned and stored in association with information items 306 by the validation tool 130. In the implementation shown in FIG. 3, the information items 306 associated with the scanned credit card receipt 303 by the validation tool 130 include the following: a first identifier 308 for the store or point of sale system that sent the credit card receipt (e.g., 303) to the remote data processor 104, a receipt date 310 that reflects the date when the credit card receipt (e.g., 303) was signed by an associated credit card holder, and a second identifier 312 for an account corresponding to the scanned credit card receipt 303. The second identifier may include all or a portion of the digits corresponding to a number of the account of the account holder's name. For example, the last four digits of the scanned account number 304 may be used as the second identifier. In one implementation, the validation tool 130 is operatively configured to recognize digits in the scanned account number 304 and generate a text representation of the last four digits of the scanned account number 304 for electronic identification of the scanned credit card receipt 303 as further discussed below. In other embodiment, different items may be included in the information items 306 to associate with each scanned credit card receipt (e.g., 50a-50n), such as the amount of each charge that may be disputed or the product (or service) associated with each charge that may be disputed. In the implementation in which the credit card receipts are sent in a batch with a batch header 60, the validation tool 130 assigns the store identifier 62 as the first identifier 308 and assigns the date 64 on the batch header 60 as the receipt date 310 for each credit card receipt 50a-50n in the batch.

Returning to FIG. 2A, the validation tool 130 then stores each of the scanned credit card receipts (e.g., 303) with the respective plurality of information items (e.g., 306). (Step 208). The validation tool 130 may store the scanned credit card receipts with the respective information items locally on secondary storage device 118 or on the database 134 operably connected to the remote data processor 102.

The validation tool 130 may then determine whether any scanned account number 304 is unreadable (step 210). In one implementation, the validation tool 130 is operatively configured to recognize that a scanned account number 304 is unreadable when digits in the scanned account number 304 can not be recognized and generated into a text representation. Alternatively, the validation tool 130 may generate a first text representation of the scanned account number 304, generate a second text representation of the scanned account number 304, and compare the first text representation to the second text representation. When the first text representation and the second text representation are not the same, the validation tool may identify the respective scanned account number 304 for the current credit card receipt 303 as unreadable.

If there is no unreadable scanned account number, the validation tool 130 proceeds to step 222 to continue processing. If there is a scanned account number 304 that is unreadable, the validation tool 130 transfers the scanned credit card receipt with the unreadable account number (e.g., the current receipt) to an operator (step 212). In one implementation, the validation tool 130 transfers the scanned credit card receipt with the unreadable account number 304 to the display 122 for inspection by an operator using the remote data processor 102. Alternatively, the validation tool 130 may transfer the scanned credit card receipt for inspection to an operator using another computer on the network 106.

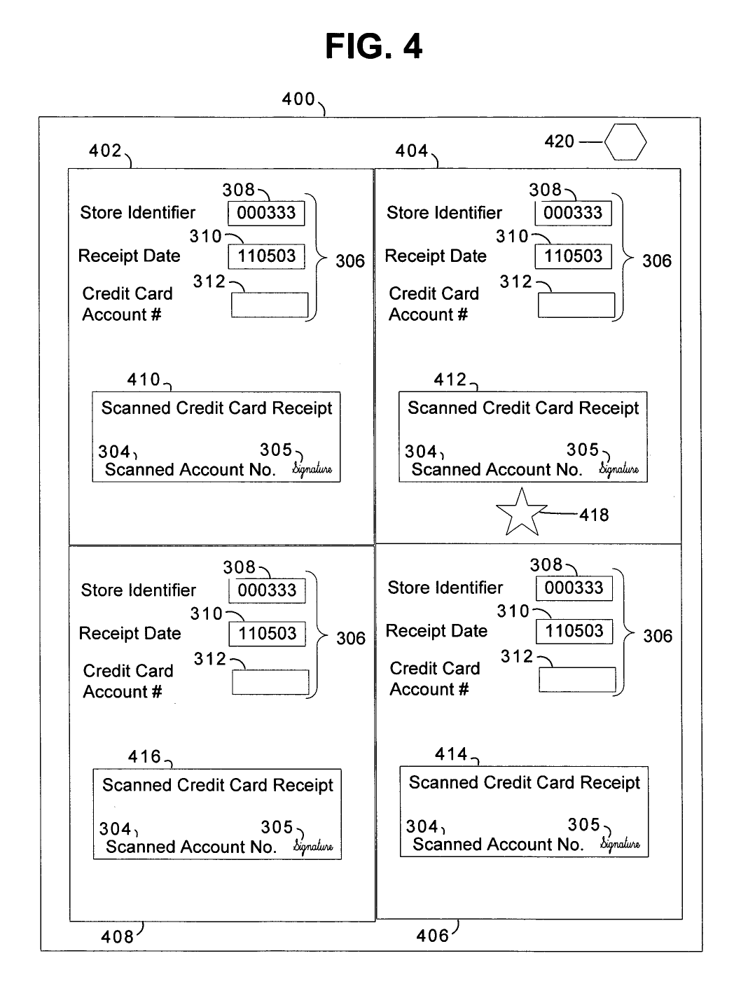

In the implementation shown in FIG. 4, the validation tool 130 submits the user interface 400 to the operator. The user interface 400 has multiple panels 402, 404, 406, and 408 for displaying a respective scanned credit card receipt 410, 412, 414, and 416. The validation tool 130 identifies to the operator a current scanned credit card receipt for inspection from among the receipts 410, 412, 414, and 416 by displaying an icon or symbol 418 in association with the current receipt (e.g., receipt 412 in FIG. 4). The validation tool 130 allows the operator to identify the unreadable scanned account number 304 associated with the current receipt 412 by entering, via a keyboard or mouse (not shown) connected to I/O device 126, all or a portion of the digits (e.g., the last four digits) of the scanned account number 304 on the current receipt 412. The operator may enter the digits of the scanned account number 304 on the current receipt 412 as the second identifier 312 in the panel 404 associated with the current receipt 412. Alternatively, the operator may indicate to the validation tool 130 that the scanned account number 304 of the current receipt 412 cannot be visually identified by sending the validation tool 130 a reject signal via a mouse click on a reject icon 420, a dedicated keyboard input (not shown in figures), or other known data input techniques. After the operator has either entered the digits of the scanned account number 304 for the current receipt 412 or identified that the scanned account number 304 of the current receipt 412 cannot be visually identified, the validation tool 130 moves the symbol 418 to the next receipt in a clock wise or counter clock wise direction (e.g., to panel 414 or 410, respectively) and replaces the current receipt 412 with another scanned credit card receipt with an unreadable account number 304. Thus, the validation tool 130 is able to support rapid inspection of multiple scanned credit card receipts in accordance with methods and systems consistent with the present invention.

Returning to FIG. 2A, the validation tool 130 then determines whether the unreadable account number was identified by the operator (step 214). In the implementation shown in FIG. 4, the validation tool 130 is able to determine whether the unreadable account number 304 of the current receipt 412 was identified in response to the operator entering the digits of the scanned account number 304 for the current receipt 412 or was not identified in response to the operator sending the validation tool 130 a reject signal. If the account number was not identified by the operator, the validation tool 130 catalogs the current receipt 412 as having an unidentifiable account number (step 216) such that the validation tool 130 is able to subsequently retrieve the current receipt 412 for inspection by the retailer 104a or a point of sale system 104b-104n when the validation tool 130 is not able to validate a disputed charge using the second identifier 312 or credit card account number assigned to scanned credit card receipts 50a-50n in accordance with methods and systems consistent with the present invention.

If the account number was identified by the operator, the validation tool 130 stores the account number identified by the operator as the second identifier for the current receipt 412 (step 218). In one implementation, the validation tool 130 may store the account number identified by the operator when the operator enters the account number as the second identifier 312 in the panel 404 in which the current receipt 412 is displayed.

Next, the validation tool 130 determines whether there are more unreadable scanned account numbers (step 220). If there are more unreadable scanned account numbers, the validation proceeds to step 212 to continue processing.

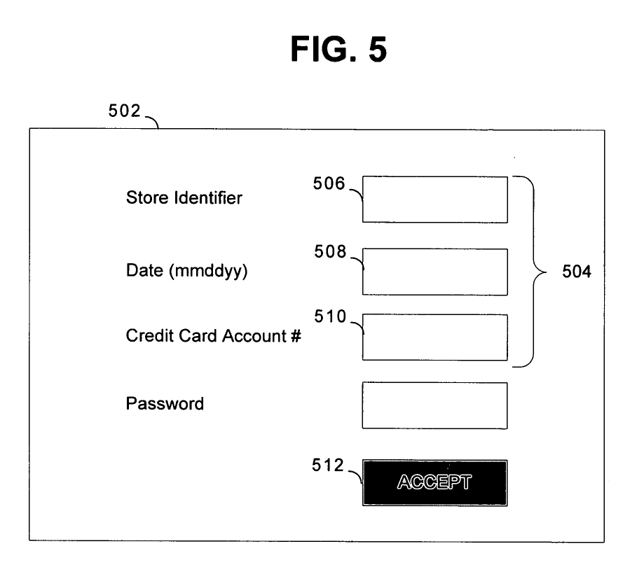

Turning to FIG. 2B, if there are no more unreadable scanned account numbers, the validation tool 130 determines whether a notice of a disputed charge has been received. (Step 222). The disputed charge may be any charge under inquiry by a corresponding credit card holder, such as a charge allegedly not made by the credit card holder, a charge that is alleged to be excessive by the credit card holder, or a charge that the credit card holder is unable to remember based on a corresponding product description. FIG. 5 depicts an exemplary user interface 502 displayed by the validation tool interface 136 to allow an authorized user of a retailer 104a or a respective point of sale system 104b-104n to submit a request for locating one of the scanned credit card receipts (e.g., one of 50a-50n scanned by the validation tool 130) associated with the disputed charge. As shown in FIG. 5, the authorized user inputs, via a keyboard or mouse (not shown) connected to I/O device 128, at least one of the information items 504 that are associated with a disputed charge, which the validation tool 130 may use to locate the one scanned credit card receipt associated with the disputed charge. The information items 504 include a first identifier 506, a receipt date 508, and a second identifier 508 that correspond to the information items 306 in FIG. 3. In the implementation shown in FIG. 5, the validation tool interface 136 allows the authorized user to submit the request or the notice of the disputed charge associated with the information items 504 when the authorized user actuates a pushbutton 512 on user interface 502. Thus, the validation tool 130 may have a pending request or notice of a disputed charge from a retailer 104a or one of the point of sale systems 104b-104n when step 222 is performed.

In another embodiment, the validation tool 130 may receive a notice of a disputed charge from one of the point of sale systems 104a-104n by downloading any disputed charge from the credit card issuer systems 108a-108n. In this embodiment, the disputed charges may be contained in a storage device 138 in FIG. 1, preferably a database, for each credit card issuer system. Each disputed charge stored in a respective storage device 138 has associated information items corresponding to information items 306. In this implementation, steps 212 and 214 may be performed for each disputed charge downloaded from the storage device 138 of each credit card system 108a-108n.

If it is determined that no notice of a disputed charge is received, the validation tool 130 ends processing. If it is determined that a notice of a disputed charge has been received, the validation tool 130 determines whether one of the stored scanned credit card receipts is associated with the disputed charge based on at least one of information items associated with the one scanned credit card receipt (step 226). For example, the validation tool 130 may use the receipt date 508 and the second identifier 510 associated with the received disputed charge notice to identify whether one of the stored scanned credit card receipts has a corresponding receipt data 310 and a corresponding second identifier 312. The validation tool 130 may also use the first identifier 506 to further limit its search of stored scanned credit card receipts to only those receipts that have a first identifier 308 corresponding to a respective retailer or point of sale system 104a-104n.

If it is determined that the one scanned credit card receipt has been stored, the validation tool 130 transmits the one scanned credit card receipt to either the point of sale system (e.g., 104a-104n) corresponding to the first identifier 506 or to a credit card issuer (e.g., 108a-108n) corresponding to the second identifier 510 so that the disputed charge may be validated.

In another embodiment, in lieu of perform steps 222 and 224 directly, the validation tool 130 may allow the one or more point of sale systems corresponding to the first identifier 506 to access the stored scanned credit card receipts over the network 106 to determine whether one of the stored credit card receipts corresponds to the information items 504 associated with the disputed charge and to transmit the one scanned credit card receipt to the credit card issuer corresponding to the second identifier 510.

If it is determined that no stored credit card receipt is associated with the disputed charge, the validation tool 130 may end processing. Alternatively, before ending processing, the validation tool 130 may use the receipt date 508 and the first identifier 510 associated with the received disputed charge notice to provide the retailer 104a or point of sale system 104b-104n that submitted the notice 500 with a list of the credit card receipts 50a-50n that have been cataloged in step 216 as having an unidentifiable account number. The retailer 104a or point of sale system 104b-104n may then identify a stored credit card receipt from the list. Upon request from the retailer 104a or the point of sale system 104b-104n, the validation tool 130 may use the first identifier 510 and a pre-determined date before or after the receipt date 508 to provide the retailer 104a or point of sale system 104b-104n with another list of the credit card receipts 50a-50n that have been cataloged in step 216 as having an unidentifiable account number. The retailer 104a or point of sale system 104b-104n may then identify a stored credit card receipt from the other list.

The foregoing description of an implementation of the invention has been presented for purposes of illustration and description. It is not exhaustive and does not limit the invention to the precise form disclosed. Modifications and variations are possible in light of the above teachings or may be acquired from practicing of the invention. Additionally, the described implementation includes software, such as validation tool 130, but the present invention may be implemented as a combination of hardware and software or in hardware alone. Note also that the implementation may vary between systems. The invention may be implemented with both object-oriented and non-object-oriented programming systems. The claims and their equivalents define the scope of the invention.

1. A method in a data processing system, the data processing system having a remote data processor and a point of sale system that are each operably connected to a network, the method comprising:
receiving a plurality of credit card receipts by the remote data processor from the point of sale system;
scanning each of the plurality of credit card receipts;
electronically associating a plurality of information items with each scanned credit card receipt, the plurality of information items including at least one of a receipt date, a first identifier for the point of sale system, and a second identifier for an account corresponding to the scanned credit card receipt;
storing each of the plurality of scanned credit card receipts with the respective plurality of information items on a storage device operably connected to the remote data processor;
receiving a notice of a disputed charge;
in response to receiving the notice of the disputed charge, determining whether one of the scanned credit card receipts stored on the storage device corresponds to the disputed charge based on said at least one of the plurality of information items associated each of the scanned credit card receipts; and
when it is determined that one of the scanned credit card receipts stored on the storage device corresponds to the disputed charge, transmitting the corresponding one scanned credit card receipt to a point of sale system corresponding to the first identifier of the information items associated with the corresponding one scanned credit card receipt.

2. The method of claim 1, wherein the at least one of the plurality of information items includes the receipt date and the first identifier for the point of sale system.

3. The method of claim 1, wherein the at least one of the plurality of information items includes the receipt date and the second identifier for the account corresponding to the one scanned credit card receipt.

4. The method of claim 1, wherein the notice of the disputed charge is received via the point of sale system.

5. The method of claim 4, wherein the step of determining whether one of the scanned credit card receipts stored on the storage device corresponds to the disputed charge is performed by the point of sale system.

6. The method of claim 5, further comprising downloading the one corresponding scanned credit card receipt to a corresponding credit card issuer in response to determining that the one corresponding scanned credit card receipt is stored on the storage device.

7. The method of claim 4, further comprising transmitting the notice of the disputed charge from the point of sale system to the remote data processor.

8. The method of claim 7, wherein the step of determining whether one of the scanned credit card receipts stored on the storage device corresponds to the disputed charge is performed by the remote data processor.

9. The method of claim 1, wherein the account corresponding to each scanned credit card receipt is derived from an account number on the respective scanned credit card receipt.

10. The method of claim 9, further comprising:
determining whether the account number for a first of the scanned credit card receipts is unreadable; and
transferring the first scanned credit card receipt to an operator for inspection in response to determining that the account number for the first scanned credit card receipt is unreadable.

11. The method of claim 9, wherein the first scanned credit card receipt is one of a subset of the scanned credit card receipts having a respective unreadable account number and further comprising:
displaying at least two of the scanned credit card receipts in the subset; and
displaying a symbol in association with one of the at least two in the subset to identify the one for inspection.

12. The method of claim 11, further comprising:
receiving an identified account number for the one scanned credit card receipt displayed in association with the symbol;
displaying another of the scanned credit card receipts in the subset in place of the one scanned credit card receipt displayed in association with the symbol; and
moving the symbol to a next one of the displayed at least two scanned credit card receipts in the subset.

13. The method of claim 12, further comprising:
electronically associating the identified account number as the second identifier for the account corresponding to the one scanned credit card receipt displayed in association with the symbol.

14. The method of claim 11, further comprising:
receiving a reject signal;
associating the reject signal with the one scanned credit card receipt displayed in association with the symbol;
displaying another of the scanned credit card receipts in the subset in place of the one scanned credit card receipt displayed in association with the symbol; and
moving the symbol to a next one of the displayed at least two scanned credit card receipts in the subset.

15. A data processing system, comprising:
a remote data processor operatively configured to connect to a point of sale system via a network;
means for receiving a plurality of credit card receipts by the remote data processor from the point of sale system;
means for scanning each of the plurality of credit card receipts;
means for electronically associating a plurality of information items with each scanned credit card receipt, the plurality of information items including at least one of a receipt date, a first identifier for the point of sale system, and a second identifier for an account corresponding to the scanned credit card receipt;
means for storing each of the plurality of scanned credit card receipts with the respective plurality of information items on a storage device operably connected to the remote data processor;
means for receiving a notice of a disputed charge;
means for, in response to receiving the notice of the disputed charge, determining whether one of the scanned credit card receipts stored on the storage device corresponds to the disputed charge based on said at least one of the plurality of information items associated each of the scanned credit card receipts; and
means for, when it is determined that one of the scanned credit card receipts stored on the storage device corresponds to the disputed charge, transmitting the corresponding one scanned credit card receipt to a point of sale system corresponding to the first identifier of the information items associated with the corresponding one scanned credit card receipt.
